(19) United States
(12) Patent Application Publication
(10) Pub. No.: US 2026/0269200 A1
(43) Pub. Date: Sep. 10, 2026

(54) INTEGRATED PLASMA ACTIVATION MEASUREMENT FOR ENHANCED PLASMA PROCESS SYSTEM

(71) Applicant: Applied Materials, Inc., Santa Clara, CA (US)

(72) Inventors: Gilho HWANG, SG (SG); Jinho AN, Palo Alto, CA (US)

(21) Appl. No.: 19/070,704

(22) Filed: Mar. 5, 2025

(51) Int. Cl. H01J 37/32; G01N 27/02

(52) U.S. Cl. CPC H01J 37/32917; G01N 27/02; H01J 2237/24564; H01J 2237/334

(57) ABSTRACT

A method includes performing, within an integrated processing platform, a plasma activation process on patterned device structures. The patterned device structures includes a dielectric layer disposed over a substrate, that includes metal pads formed therein. The method further includes performing, within the integrated processing platform, an electrical measurement process on the patterned device structures to measure a degree of plasma activation of a field region of the dielectric layer of each of the patterned device structures.

### BACKGROUND

### Field

Embodiments of the present invention generally relate to a system and method for processing substrates, in particular, performing a plasma activation process on a dielectric layer of a substrate device.

### Description of the Related Art

Hybrid bonding is used to bond corresponding patterned device structures (i.e., dies) that include a dielectric layer and metal pads. Prior to bonding two corresponding patterned device structures, a plasma activation process is performed to activate the dielectric layers of the patterned device structures in order to improve the adhesion of the dielectric layer and improve the quality of the bond. The plasma activation process is one of the most critical process of hybrid bonding. The plasma activation of the dielectric layer enables hybrid bonding, by making the dielectric surface layer hydrophilic to form Van der Waals bonds.

However, after the plasma activation process, there is no current method to measure or detect the degree of plasma activation of the dielectric layer of the patterned device structures. Current approaches to measure the degree of plasma activation of the dielectric layer include water droplet contact angle measurement processes and etch rate measurement processes. However, current contact angle measurement processes are unable to capture the subtle differences in the degree of plasma activation of dielectric layers between different patterned device structures.

Etch rate measurement processes measure the intensity of the plasma generated during the plasma activation process using external measurement tools. However, the external measurement tools do not directly correlate to the plasma activation of the dielectric layer and inherently reduces efficiency and effectiveness of the bonding process.

Another solution is to measure the degree of plasma activation of the dielectric layer is to use a tool external to the hybrid bonding platform. However, using an external tool increases the processing time of the hybrid bonding process, and can cause inaccurate plasma activation measurements due to atmospheric contamination of the dielectric layer.

Therefore, there is a need for an integrated method for accurate measurement of the degree of plasma activation of the dielectric layer of patterned device structures.

### SUMMARY

According to one or more embodiments, a method includes performing, within an integrated processing platform, a plasma activation process on patterned device structures, wherein the patterned device structures comprise a dielectric layer disposed over a substrate, the dielectric layer including metal pads formed therein, and performing, within the integrated processing platform, an electrical measurement process on the patterned device structures to measure a degree of plasma activation of a field region of the dielectric layer of each of the patterned device structures.

According to one or more embodiments, an integrated processing platform includes an equipment front end module (EFEM) configured to receive a patterned device structures comprising a dielectric layer disposed over a substrate, the dielectric layer including metal pads formed therein, a surface preparation module configured to activate a field region of the dielectric layer of the patterned device structures using a plasma activation process, and an electrical measurement module configured to measure a degree of plasma activation of the field region of the dielectric layer of the patterned device structures.

According to one or more embodiments, an electrical measurement module includes a substrate support comprising a grounded electrode configured to secure a patterned device structure comprising a dielectric layer disposed over a substrate, the dielectric layer including metal pads formed therein, a first probe configured to be electrically connected to a field region of the dielectric layer of the patterned device structure, and a second probe configured to be electrically connected to the grounded electrode, wherein the electrical measurement module is configured to measure a difference in an electrical characteristic measured by the first probe and the second probe. and a measurement system comprising a power source configured to provide a voltage or a current to the first probe and the second probe

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1A-1C illustrate schematic diagrams of a packaged device during bonding according to one or more embodiments.

FIG. 2 illustrates operations for a method 200 for bonding according to one or more embodiments.

FIG. 3 is a schematic illustration of an exemplary integrated processing platform 300 for advanced packaging according to one or more embodiments.

FIGS. 4A-4C are schematic illustrations of an exemplary electrical measurement system according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

During hybrid bonding of two corresponding patterned device structures (i.e., dies), dielectric layers of the patterned device structures undergo a plasma activation process. For example, during a hybrid bonding process a die may include a dielectric layer formed over a substrate. The substrate may also include multiple layers of dielectric materials and metal wiring known as back-end-of-the line (BEOL) layers. In one example, a dielectric layer can be the last layer of BEOL, or an additional layer deposited specifically for hybrid bonding.

The plasma activation process is performed on the field region of the dielectric layer to activate the dielectric layers of the patterned device structures in order to improve the adhesion of the dielectric layer and improve the quality of the bond. However, methods to determine the degree of the plasma activation of the dielectric layers of dies in situ with a hybrid bonding platform are inaccurate. Furthermore, determining the degree of plasma activation of the dielectric layers of dies using an external tool reduces the efficiency of the hybrid bonding process and produces inaccurate results and impair the hybrid bonding process due to atmospheric contamination formed on the dielectric layers during transfer to the tools.

Embodiments herein relate to an integrated processing platform that includes an electric measurement module that allows for integrated measurement of the degree of the plasma activation of the dielectric layer of the dies after plasma activation process(es). Advantageously, the electric measurement module allows for precise and accurate measurement of the degree of plasma activation of the dielectric layer of dies, decreases the time required to measure the degree of plasma activation, and allows for continuous monitoring of the degree of plasma activation of the dielectric layer.

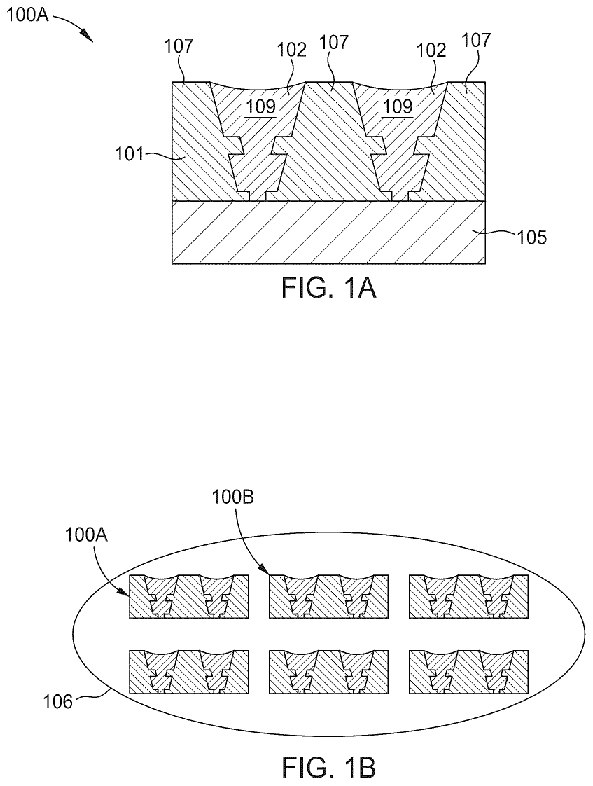

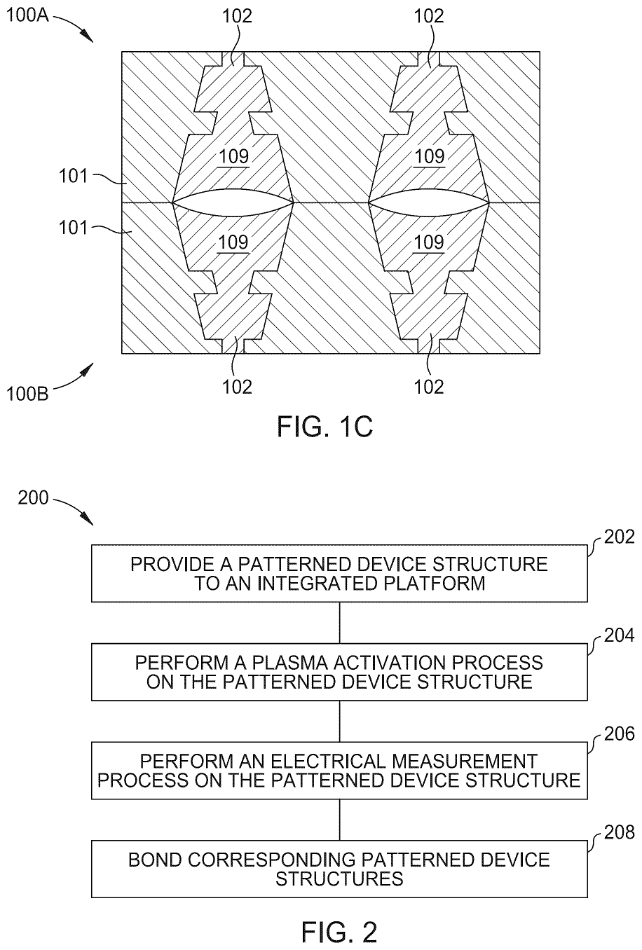

FIGS. 1A-1C illustrate schematic diagrams of a packaged device during bonding according to one or more embodiments. FIG. 2 illustrates operations for a method 200 for bonding according to one or more embodiments.

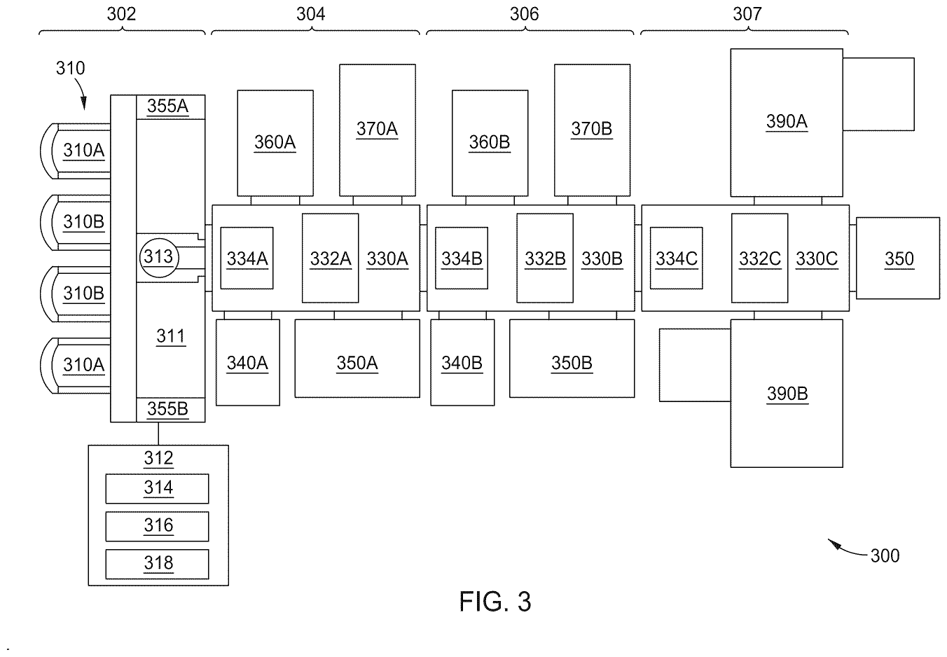

At operation 202 of the method 200, a patterned device structure 100A is provided to an integrated processing platform 300. Details on the integrated processing platform 300 are described in more detail in FIG. 3 below.

In one or more embodiments, as shown in FIG. 1A, the patterned device structure 100A includes a dielectric layer 101 formed over a die 105. As noted above, the patterned device structure 100A is one of numerous patterned device structures (dies or chips) formed across a base substrate (i.e., “a substrate”). In one example, the numerous patterned device structures (also referred to as “dies”) are formed across the substrate in a grid-like fashion. In one example, the operations described herein are performed on each patterned device structure formed on the substrate. The substrate includes multiple layers of metal wiring in insulating dielectrics that are commonly referred to as the Back-End-of-Line (BEOL) layers or redistribution layers (RDLs). The dielectric layer 101 may include an inorganic dielectric material layer such as oxide, nitride, oxynitride, oxycarbide, carbides, carbonitrides, diamond, diamond like materials, glasses, ceramics, glass-ceramics, and the like. In some other embodiments, the dielectric layer 101 may include an organic material containing layer. In one or more examples, the dielectric layer 101 is a layer deposited specifically for hybrid bonding and/or is the last of the BEOL layers.

In one example, interconnect structures 102 are embedded (i.e., are etched) in the dielectric layer 101. In one example, the interconnect structures 102 are positioned such that the interconnect structures 102 can be mated during bonding to form continuous conductive interconnects. The interconnect structures 102 may be formed using any suitable etching process such as a damascene etching process.

As understood by those with ordinary skill in the art, the interconnect structures 102 are filled with an interconnect material that is deposited over the patterned device structure 100A. In one example, the interconnect material covers the dielectric layer 101 and fills the interconnect structures 102. In one or more embodiments, the interconnect material is a conductive material. The interconnect material may comprise any suitable conductive material such as copper (Cu). In one example, the interconnect material includes a copper barrier seed layer (CuBS) that includes multiple metal containing layers such as tantalum, titanium, and copper.

In embodiments in which the interconnect material covers the dielectric layer, a chemical mechanical polishing (CMP) process is performed on each of the patterned device structures (e.g., patterned device structure 100A). The CMP process removes the interconnect material from a field region 107 (i.e., the unetched portions) of the dielectric layer 101, leaving interconnect regions such as pads 109 formed within interconnect structures 102. In embodiments in which a CMP process is performed, the pads 109 may include dishing as illustrated in FIG. 1A.

On the other hand, the interconnect material is deposited in a manner such that the interconnect material only fills the interconnect structures 102. Therefore, the pads 109 can be formed without performing a CMP process and/or without dishing present.

In one or more embodiments, multiple patterned device structures (i.e., the substrate) are secured to a tape frame and are provided to the integrated processing platform 300. The patterned device structure 100A is one of multiple patterned device structures (i.e., “dies”) that are secured to a tape frame 106 (i.e., die-to-wafer bonding). As noted above, the substrate includes multiple dies, and therefore multiple patterned device structures.

As shown in FIG. 1B, the substrate secured to the tape frame 106, includes source and target patterned device structures that are configured to be bonded to one another. For example, the patterned device structure 100A may be a source patterned device structure (i.e., a source die) and a patterned device structure 100B may be a target patterned device structure (i.e., a target die) configured to be bonded together. In one embodiment, each die is separated from one another after being secured in the tape frame 106. In another embodiment, each die is provided to the integrated processing platform 300 without being secured to the tape frame. In other embodiments, each of the patterned device structures (such as the patterned device structure 100A) are supplied to the integrated processing platform 300 individually.

At operation 204 of the method 200, a plasma activation process is performed on the patterned device structure 100A. As will be described in more detail below, the plasma activation process is performed by a plasma module within the integrated processing platform 300. The plasma activation process is used to activate the dielectric layer 101 of the patterned device structure 100A. In one or more embodiments, if the patterned device structure is one of multiple patterned device structures on the substrate, the dielectric layer 101 of each patterned device structure (including, but not limited to, patterned device structure 100A) undergo the plasma activation process. The plasma activation process may be used to activate and/or clean at least the field region 107 of the dielectric layer 101. During the plasma activation process, the dielectric layer 101 of the patterned device structure(s) (i.e., the field region 107 of the dielectric layer 101 of the patterned device structure(s)) are exposed to a plasma, which contains charged particles such as ions and electrons. These high-energy ions bombard the dielectric layer 101 of the patterned device structure(s), and the formed plasma activated gas species remove contaminants and activate the dielectric layer 101 by creating reactive sites that increase surface energy and wettability. In one or more examples, the plasma activation process makes the dielectric layer 101 of the patterned device structure(s) of each die more hydrophilic and chemically reactive, promoting better adhesion and bonding quality in the hybrid bonding process.

In one or more examples, prior to the plasma activation process, the patterned device structures may also undergo optional pre-treatment process(es). In one or more examples, the pre-treatment process(es) includes, but is not limited to, cleaning the patterned device structure(s) to remove atmospheric contaminants. In one or more examples, the pre-treatment process(es) is performed within the integrated processing platform 300. In other embodiments, the pre-treatment process(es) is performed in a separate tool. The pretreatment process can include a wet or dry pre-cleaning type of process.

As noted above, the degree of plasma activation of the dielectric layer 101 of each of the patterned device structure(s) is indicative of the degree of adhesion and bonding quality of a subsequent hybrid bonding process between source die(s) (patterned device structure 100A) and target die(s) (patterned device structure 100B). For example, the higher the degree of plasma activation of the dielectric layer 101 of the patterned device structure 100A and the patterned device structure 100B, the higher the degree of adhesion and bonding quality of the hybrid bonding process.

However, as noted above, a method for accurately measuring the degree plasma activation of the dielectric layer 101 does not exist. Advantageously, and as will be described in more detail below, the integrated processing platform 300 includes an electrical measurement module 355A (FIG. 3) for an accurate in situ measurement of the degree of plasma activation of the dielectric layer 101 of the patterned device structures.

At operation 206 of the method 200, an electrical measurement process is performed on the patterned device structure 100A. The electrical measurement process is performed by the electrical measurement module 355A within the integrated processing platform 300 (FIG. 3). In one or more embodiments, the electrical measurement process includes measuring the degree of plasma activation of the field region 107 of the dielectric layer 101. In embodiments, in which the patterned device structure 100A is one of a plurality of device structures provided to the integrated processing platform 300, the plasma activation of the dielectric layer 101 of each patterned device structure is measured. If the plurality of device structures are on a tape frame 106 (FIG. 1B), the electrical measurement process is performed after the patterned device structures are released from the tape frame 106. This will also be described in more detail in FIG. 3 below.

At operation 208 of the method 200, as illustrated in FIG. 1C, corresponding patterned device structures (i.e., source and target dies) are bonded to each other. In one example, the source and target dies are bonded using hybrid bonding. In one or more examples, the bonding is performed within the integrated processing platform 300. In other embodiments, the bonding is performed in a separate tool.

On the other hand, the degree of plasma activation of the dielectric layer may be measured continuously throughout the method 200.

FIG. 3 is a schematic illustration of an exemplary integrated processing platform 300 for advanced packaging according to one or more embodiments. In one example, the integrated processing platform 300 comprises an Equipment Front End Module (EFEM) 302, responsible for loading and unloading substrate(s) from multiple loading ports (i.e., cassettes) 310, surface preparation modules 304 and 306, which are designed to optionally perform pre-treatment processes and perform the plasma activation process on the substrates in preparation for bonding, a bonding module 307 responsible for executing the hybrid bonding process, an electrical measurement module 355A, and a system controller 312, which manages and coordinates the operation of the various modules within the integrated processing platform 300.

The EFEM 302, includes a support structure configured to accommodate a plurality of loading ports 310 that are adapted to retain substrates. The EFEM 302 further includes a housing 311 enclosing a chamber that provides a controlled environment for the handling and processing of the substrates. In addition, the EFEM 302 is equipped with one or more factory interface robots 313 that are operatively connected to the chamber and configured to transfer the substrates between the loading ports 310 and various modules of the integrated processing platform 300.

The surface preparation modules 304 performs a series of the optional pre-treatment process and the plasma activation process (operation 204) on substrates using an integrated and automated system. In one example, the surface preparation module 304 comprises an Automated Modular Mainframe (AMM) 330A, a brush box clean module 340A, a wet clean module 350A, a degas module 360A, and a plasma module 370A.

The AMM 330A serves as the central hub of the systems, coordinating the transfer of substrates between different sub-modules. The AMM 330A and utilizes a substrate transfer robot that moves the substrates between various process stations, ensuring precise handling and minimizing the risk of contamination or damage. The AMM 330A includes a substrate aligner 332A and an in-line metrology system 334A. The substrate aligner 332A and is configured to accurately align the substrates, ensuring that they are positioned precisely according to the requirements of the bonding process. The in-line metrology system 334A is adapted to measure and verify the substrate surface characteristics, including cleanliness, activation level, and other relevant parameters, both before and after the cleaning and activation operations performed by the surface preparation module 304.

The brush box clean module 340A provides a mechanical cleaning of the substrate surfaces, removing particles and contaminants using brushes or other mechanical scrubbing means. The brush box clean module 340A can be customized to use different brush materials, rotational speeds, and cleaning chemistries to achieve the desired level of cleanliness.

The wet clean module 350A is responsible for chemical cleaning of the substrates, using various liquid cleaning agents to remove contaminants that may not be effectively removed by mechanical means. The liquid cleaning agents can include deionized water, acids, bases, or other specialized chemistries, depending on the specific requirements of the process and substrate materials.

The degas module 360A is configured for outgassing the substrates by removing residual liquids, gases and contaminants that may have been adsorbed or trapped on the substrate surfaces during prior processing operations. This operation ensures that the substrate surface is free of contaminants that might interfere with subsequent processing operations.

The plasma module 370A performs the plasma preparation process which includes the plasma activation process (operation 204). The plasma module 370A is designed and configured for effective and efficient radical/plasma RPS/RF plasma activation processes and/or cleaning processes. The plasma module 370A includes a Remote Plasma Source (RPS) that can be selectively positioned on the top, side wall, or any combination thereof of the chamber, providing flexibility in RPS placement. The RPS is further equipped with engineered hardware components, such as baffles and/or diffuser plates, which facilitate uniform distribution of gases or radicals within the chamber, thereby ensuring consistent process control and reproducibility. Suitable RPSs may include, but are not limited to, radio frequency (RF) or very high radio frequency (VHRF) capacitively coupled plasma (CCP) sources, inductively coupled plasma (ICP) sources, microwave-induced (MW) plasma sources, electron cyclotron resonance (ECR) chambers, or high-density plasma (HDP) chambers.

In one or more examples, the plasma module 370A is configured to operate in a variety of RPS/RF processes, including, but not limited to, RPS, RF plasma, RF-assisted RPS, RPS-assisted RF plasma, or intermittent RPS/RF processing. The plasma module 370A is further adapted to utilize a range of RPS/RF clean or activation gas chemistries, comprising, but not limited to, H₂, N₂, Ar, He, NH₃, NF₃, and CDA.

The surface preparation module 306 may include similar sub-modules or alternative sub-modules as needed to address specific substrate cleaning and plasma activation requirements. Collectively, the surface preparation modules 304 and 306 ensure that the substrates are thoroughly cleaned and activated, preparing them for the subsequent bonding process within the integrated processing platform 300. In one or more embodiments, the surface preparation module 306 is optional. Furthermore, as described above the pre-treatment processes are optional. Therefore, in one or more embodiments, the surface preparation module 304 only includes the plasma module 370A, and the surface preparation module 306 (if included) only includes the plasma module 370B.

The bonding module 307 is responsible for executing the bonding of dies from the substrates (operation 208), following the plasma activation process (operation 204) and the electrical measurement process (operation 206). The bonding module 307 includes an AMM 330C, a UV module 350, and one or more bonders 390. The AMM 330C serves as the central control unit, managing and coordinating the operations of the UV module 350 and the bonder 390 to ensure efficient and accurate die bonding. The UV module 350 is responsible for weakening the tape frame 106 (FIG. 1B) holding the dies. By exposing the tape frame 106 to UV light, the tape frame's molecular structure changes, reducing its strength and allowing for the easy release of dies without causing damage. Finally, the bonder 390 performs the pick, flip, placement, and bonding of dies. With the use of a highly accurate robotic system, the bonder 390 ensures precise alignment and positioning of dies throughout the hybrid bonding process. For example, it picks up the target dies (i.e., the patterned device structure 100B) from the substrate, flips them to the correct orientation, accurately places them onto a corresponding source die (i.e., the patterned device structure 100A), and initiates the bonding process, which may involve pressure, heat, or both. In one or more embodiments, the bonding module 307 is optional, and hybrid bonding is performed in a separate hybrid bonding tool.

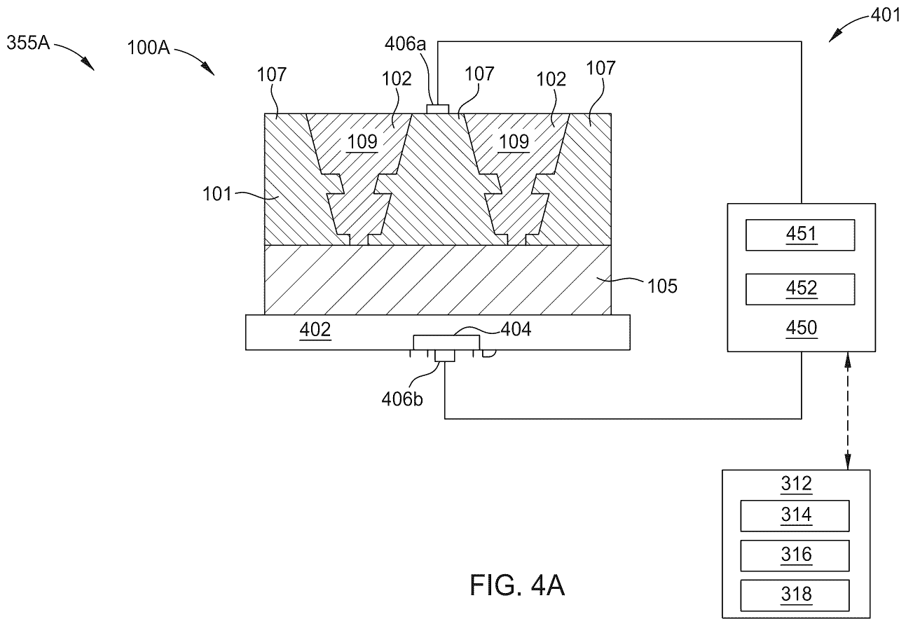

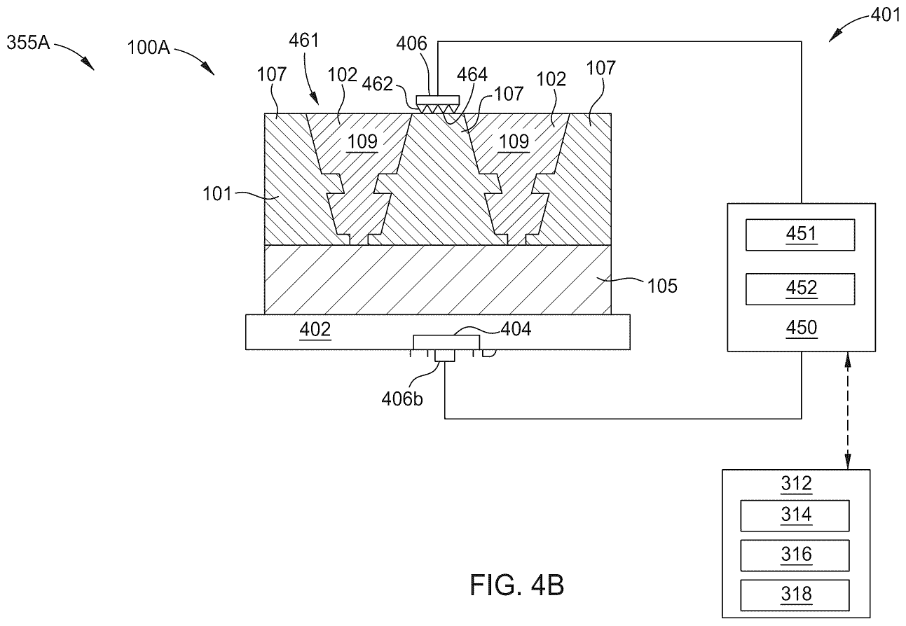

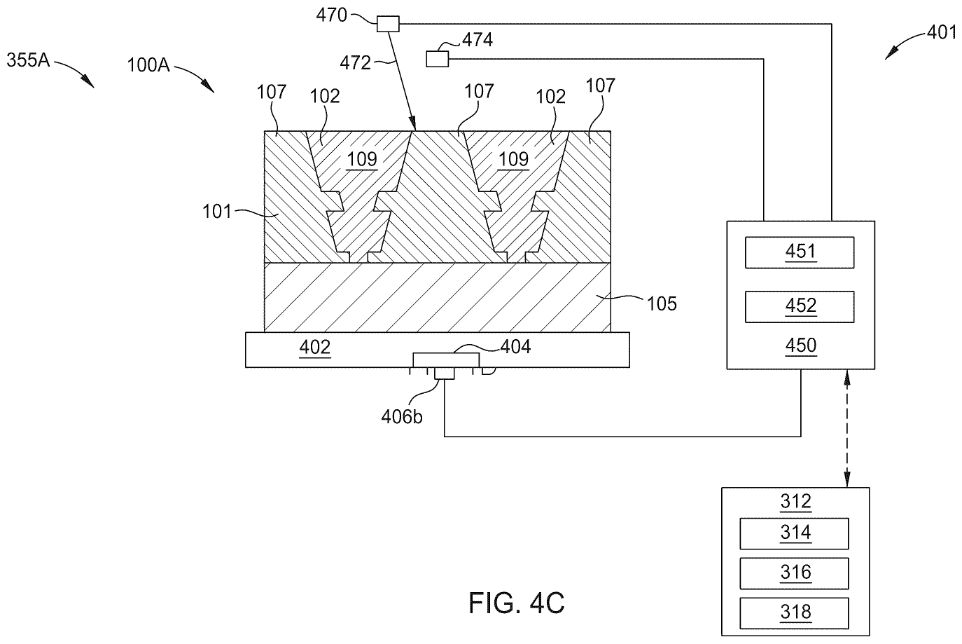

FIGS. 4A-4C are schematic illustrations of an exemplary electrical measurement modules according to one or more embodiments. In one or more embodiments, as shown in FIG. 4A, the electrical measurement module 355A includes an electrical measurement device 401. The electrical measurement device 401 is operable to measure the degree of plasma activation of the field region 107 of the dielectric layer 101 of the patterned device structure(s) (operation 206) prior to hybrid bonding. In one or more embodiments, the electrical measurement device 401 includes a substrate support 402, a measurement system 450 and one or more probes 406a-406b. In one or more examples, the substrate support 402 includes a grounded electrode 404, such as an electrode embedded within a vacuum chuck and one or more probes to measure the degree of plasma activation of the dielectric layer 101 of the patterned device structures. The grounded electrode within the vacuum chuck can be used to secure a patterned device structure (i.e., a die or a substrate) to the surface of the vacuum chuck. In one or more embodiments, a first probe 406a is positioned to contact the field region 107 of the dielectric layer 101 and a second probe 406b is electrically connected to the grounded electrode 404. In one or more embodiments, to measure the degree of plasma activation of the field region 107 of the dielectric layer 101 of the patterned device structures, a voltage or current is applied to the dielectric layer 101 through the probes 406a-406b by use of a power source 451 within the measurement system 450. The applied voltage or current provided to the probes 406a-406b by the power source 451 and a sensor 452 within the measurement system 450 are used to detect and/or measure the difference of one or more electrical characteristics (e.g., current flow, capacitance, voltage, etc.) of the patterned device structure (i.e., the dielectric layer 101 and the grounded electrode). For example, the sensor 452 may be used to measure the difference in current (leakage current) through the dielectric layer 101, the capacitance through the dielectric layer 101 and the grounded electrode, or the like. Then based on the measured electrical characteristic(s) the degree of plasma activation of the surface of the dielectric layer 101 can be determined. In some cases, the degree of a measured electrical characteristic can be determined to be acceptable when the system controller 312 compares the measured electrical characteristic(s) with a threshold electrical characteristic that is stored in memory 316 of the system controller 312. In one example, an algorithm running in the system controller 312 compares a stored threshold leakage current value or a threshold capacitance value with the measured electrical characteristic to determine the degree of plasma activation. For example, the higher the leakage current based on an applied voltage, the higher the degree of plasma activation. The higher the degree of the plasma activation of the dielectric layer 101, the higher the quality of adhesion and hybrid bonding between a source and a target die. Furthermore, the integrated processing platform 300 may also include an electrical measurement modules 355B that includes electrical measurement devices (e.g., measurement system 450) configured to measure the plasma activation the plasma activation of the field region 107 of the dielectric layer 101 of the patterned device structures. Stated differently, multiple electrical measurements modules (355A and 355B) can be used to perform the electrical measurement process.

The system controller 312, such as a programmable computer, is coupled to the integrated processing platform 300 for controlling one or more of the components therein. In one embodiment, the system controller 312 controls the electrical measurement module(s), and determines the degree of plasma activation of the dielectric layer of the patterned device structures. In one embodiment, the system controller 312 may control the wafer handling and transferring between different processing modules to perform a process sequence. In another embodiment, the system controller 312 may control the operation of brush box cleaning module 340, which is described further below. In operation, the system controller 312 enables data acquisition and feedback from the respective components to coordinate processing in the integrated processing platform 300. The system controller 312 includes a programmable central processing unit (CPU) 314, which is operable with a memory 316 (e.g., non-volatile memory) and support circuits 318. The support circuits 318 (e.g., cache, clock circuits, input/output subsystems, power supplies, etc., and combinations thereof) are conventionally coupled to the CPU 314 and coupled to the various components within the integrated processing platform 300. In one or more embodiments, the threshold values and an algorithm which includes instructions to perform the measurement process is stored in the memory 316.

In one or more embodiments, as shown in FIG. 4B, the electrical measurement device 401 may measure the degree of plasma activation of the field region 107 of the dielectric layer 101 from only a top side 461 of the patterned device structure 100A. In one or more embodiments, the electrical measurement device 401 includes a four-point probe 460. The four-point probe includes two outer probes 462 and two inner probes 464 that are positioned to contact a portion of the field region 107 of the dielectric layer 101. A voltage or current is applied to the dielectric layer 101 through the outer probes 462 by use of the power source 451 within the measurement system 450. The degree of plasma activation of the dielectric layer 101 is measured by the sensor 452 by measuring the one or more electrical characteristics captured by the inner probes 464 and comparing the measured one or more electrical characteristics to one or more threshold electrical characteristics.

In one or more embodiments, the electrical measurement device may measure the degree of plasma activation of the field region 107 of the dielectric layer 101 without contacting the patterned device structure 100A. In one or more examples, the measurement system 450 may be further coupled to an emitter 470 and a detector 474. The emitter 470 provides an electron beam 472 to the dielectric layer 101 by use of the power source 451. For example, the emitter 470 provides the electron beam 472 to the field region of the dielectric layer. The detector 474, based on the electron beam 472, detects the field, or the back scattering of electrons on the field region 107. Based on the field, or the back scattering of electrons detected by the detector 474, the sensor 452 measures the degree of plasma activation by measuring the one or more characteristics of the dielectric layer 101 and comparing the measured one or more electrical characteristics to one or more threshold electrical characteristics.

### Processing Sequence Example

In operation, the hybrid bonding begins by loading a substrate including patterned device structures (e.g., patterned device structures 100A and 100B) onto the EFEM 302 by one or more factory interface robots 313. The substrates are then transported through the integrated processing platform 300 by the AMM 330A and 330B.

Next, the substrates are aligned using the substrate aligners 332A and 332B to ensure accurate die placement during the bonding process. The aligned substrates are then transported to the brush box cleaning modules 340A and 340B, for cleaning. The brush box cleaning modules 340A and 340B may include a housing configured to enclose the substrates, a plurality of brushes configured to engage with the substrate surface, and a cleaning agent delivery system configured to deliver a cleaning agent to the plurality of brushes.

After the initial brush box cleaning, the substrates are subjected to a wet cleaning operation in the wet clean modules 350A and 350B, which may involve the delivery of cleaning and rinsing fluids along with the use of megasonic or atomizer cleaning methods to remove contaminants from the substrate surface.

Following the wet cleaning, the substrates are transported to the degas modules 360A and 360B, where unwanted gases, moisture, or contaminants are removed from the surface of a substrate or a die containing work piece. The degas process typically involves heating the substrate or work piece to a specific temperature, causing the contaminants, trapped gases, or moisture to evaporate or desorb from the surface. In some cases, the process may also involve applying a vacuum or an inert gas to facilitate the removal of contaminants. Proper degassing can improve adhesion, reduce defects, and enhance the overall performance of the semiconductor device, particularly in the context of die-stack hybrid bonding applications.

The degassed substrates 310A and 310B then undergoes the plasma preparation process which includes a plasma activation process (operation 204) in the plasma modules 370A and 370B for surface activation, and/or further optional cleaning. During the plasma activation process, the surfaces of the patterned device structures (i.e., the field region 107 of the dielectric layer 101 of the patterned device structures) are exposed to the plasma, which contains charged particles such as ions and electrons. These high-energy ions bombard the surface, removing contaminants and activating the surface (i.e., the field regions 107 of the dielectric layer 101) by creating reactive sites that increase surface energy and wettability. This plasma activation process makes the field region 107 of the dielectric layer 101 of the patterned device structure of each die more hydrophilic and chemically reactive, promoting better adhesion and bonding quality in the hybrid bonding process.

Afterwards, the substrates are transferred into the chamber of AMM 330C and are subsequently treated in a UV module 350 coupled to the AMM 330C to facilitate the release of the patterned device structures from the tape frame 106 prior to bonding. The UV module 350 works by exposing the tape frame 106, which holds the patterned device structures, to UV light. The high-energy UV photons interact with the tape frame 106, causing the tape frame's molecular structure to change. This change results in a reduction of the adhesive strength, allowing the patterned device structures to be easily released from the tape frame 106. In one or more embodiments, treating the substrates in the UV module is optional if the patterned device structures (e.g., patterned device structures 100A and 100B) are not secured to the tape frame 106.

After releasing the substrates from the tape frame 106, the substrates are transferred to the electrical measurement module 355A. As noted above, a first probe 406a is placed on the field region 107 of the dielectric layer 101 and a second probe 406b is coupled to the grounded electrode 404 (i.e., the vacuum chuck) and the plasma activation of the field region 107 of the dielectric layer 101 is measured by use of the measurement system 450.

Finally, the patterned device structures of each die of the substrates are bonded using a hybrid bonding process performed by the bonder 390A or bonder 390B. In the bonder 390, the process of bonding begins with the precise alignment bonding sites between the dies. This alignment is achieved using advanced alignment systems, such as high-resolution cameras and pattern recognition algorithms, which accurately align the pads 109 and the surrounding field region 107 (i.e., unetched portions) of the dielectric layer 101 formed on each of the patterned device structures.

Once the alignment is achieved, the bonder 390 picks up the individual patterned device structures (i.e. dies) using a pick-and-place mechanism. This mechanism may comprise a vacuum-based gripping system or other appropriate mechanisms suitable for handling semiconductor dies. In one example each of the target patterned device structures (i.e., patterned device structure 100B) are picked and dies are then flipped over and brought into close proximity with the corresponding source patterned device structures (i.e., patterned device structure 100A) for bonding.

The bonder 390 then applies a controlled force and temperature to the source and target patterned device structures to initiate the bonding process. The force and temperature applied during the bonding process depends on the specific bonding technique being used, such as thermo-compression bonding or direct bonding. The bonding process may involve the formation of molecular bonds between the dielectric layers and the fusing of copper pads to establish electrical connections.

Throughout the bonding process, the bonder 390 is equipped with sensors and feedback systems to monitor critical parameters, such as force, temperature, and alignment accuracy. This real-time monitoring enables fine-tuning and control of the bonding process to ensure optimal bonding performance and yield.

After the bonding process is completed, the bonded patterned device structures (i.e., the bonded dies) form a stacked semiconductor structure as shown in FIG. 1C, with the source patterned device structure (patterned device structure 100A) being bonded to the target patterned device structure (patterned device structure 100B). The bonder 390 then repeats this process for the remaining patterned device structures, iteratively creating a vertically integrated stack of dies or substrates.

In the die-to-substrate bonding embodiment, individual patterned device structures (dies) are bonded to a receiving substrate, which may contain pre-patterned bond pads or other structures for facilitating the bonding process. The patterned device structures and receiving substrate are first subjected to the cleaning, degassing, plasma activation, and UV curing operations as described previously. The bonders 390 are configured to pick up the individual patterned device structures, align them with the receiving substrate, and bond them using a hybrid bonding process. This process may involve aligning the pads 109 on the patterned device structures with corresponding pads on the receiving substrate, and applying pressure and heat to form a strong bond between the patterned device structures and the receiving wafer.

While the foregoing is directed to embodiments of the present disclosure, other and further embodiments of the disclosure may be devised without departing from the basic scope thereof, and the scope thereof is determined by the claims that follow.

What is claimed is:

1. A method comprising:
performing, within an integrated processing platform, a plasma activation process on patterned device structures, wherein the patterned device structures comprise a dielectric layer disposed over a substrate; and
performing, within the integrated processing platform, an electrical measurement process on the patterned device structures to measure a degree of plasma activation of a field region of the dielectric layer of each of the patterned device structures.

2. The method of claim 1, wherein the electrical measurement process is performed within an electrical measurement module comprising a four-point probe.

3. The method of claim 1, wherein the electrical measurement process is performed within an electrical measurement module that comprises a substrate support comprising a grounded electrode, a first probe, and a second probe connected to a measurement system comprising a power source and a sensor.

4. The method of claim 3, wherein the electrical measurement process comprises:
electrically connecting the first probe to the field region of the dielectric layer of a patterned device structure positioned on the substrate support;
electrically connecting the second probe to the grounded electrode;
providing, by the power source, a voltage or a current to the first probe and the second probe;
measuring, by the sensor, an electrical characteristic of the patterned device structure; and
comparing, by a system controller of the integrated processing platform, a difference in the measured electrical characteristic and a threshold electrical characteristic.

5. The method of claim 4, wherein the electrical characteristic comprises a difference in current through the dielectric layer or capacitance through the dielectric layer and the grounded electrode.

6. The method of claim 5, further comprising bonding, by the integrated processing platform, corresponding patterned device structures.

7. The method of claim 1, wherein the electrical measurement process is performed above a top side of the patterned device structures.

8. The method of claim 1, wherein the electrical measurement process is performed without contacting the patterned device structures.

9. An integrated processing platform comprising:
an equipment front end module (EFEM) configured to receive a patterned device structures comprising a dielectric layer disposed over a substrate;
a surface preparation module configured to activate a field region of the dielectric layer of the patterned device structures using a plasma activation process; and
a electrical measurement module configured to measure a degree of plasma activation of the field region of the dielectric layer of the patterned device structures.

10. The integrated processing platform of claim 9, wherein the electrical measurement module comprises one or more electrical measurement devices comprising:
a substrate support comprising a grounded electrode configured to secure a patterned device structure;
a first probe configured to be electrically connected to the field region of the dielectric layer of a patterned device structure; and
a second probe configured to be electrically connected to the grounded electrode; and
a measurement system comprising power source configured to provide a voltage or a current to the first probe and the second probe.

11. The integrated processing platform of claim 10, wherein the measurement system further comprises a sensor configured to measure an electrical characteristic of the patterned device structure based on the provided voltage or current to the first probe and the second probe.

12. The integrated processing platform of claim 11, wherein the electrical characteristic comprises a difference in current through the dielectric layer or capacitance through the dielectric layer and the grounded electrode.

13. The integrated processing platform of claim 9, wherein the surface preparation module is further configured to perform one or more pre-treatment process on the patterned device structures prior to the plasma activation process.

14. The integrated processing platform of claim 9, wherein the electrical measurement module comprises one or more electrical measurement devices comprising a four-point probe.

15. The integrated processing platform of claim 9, wherein the electrical measurement module comprises one or more electrical measurement devices comprising a detector configured to provide an electron beam to the dielectric layer and a detector configured to detect a field or back scattering of electrons on the dielectric layer based on the electron beam.

16. An electrical measurement module comprising:
a substrate support comprising a grounded electrode configured to secure a patterned device structure comprising a dielectric layer disposed over a substrate,;
a first probe configured to be electrically connected to a field region of the dielectric layer of the patterned device structure; and
a second probe configured to be electrically connected to the grounded electrode, wherein the electrical measurement module is configured to measure a difference in an electrical characteristic measured by the first probe and the second probe.

17. The electrical measurement module of claim 16, further comprising a measurement system comprising a sensor configured to measure an electrical characteristic of the patterned device structure.

18. The electrical measurement module of claim 16, wherein the electrical measurement module is included in an integrated processing platform that comprises a surface preparation module configured to perform a plasma activation process on the patterned device structure.

19. The electrical measurement module of claim 18, wherein the surface preparation module is further configured to perform a pre-treatment process on the patterned device structure prior to performing the plasma activation process.

20. The electrical measurement module of claim 16, wherein the electrical measurement module is included in an integrated processing platform that further comprises a bonding module configured to bond corresponding patterned device structures.
